(19) United States
(12) Patent Application Publication
(10) Pub. No.: US 2011/0290288 A1
(43) Pub. Date: Dec. 1, 2011

(54) POWER GENERATION UMBRELLA

(76) Inventor: JOEN-SHEN MA, Taipei (TW)

(21) Appl. No.: 12/789,778

(22) Filed: May 28, 2010

(51) Int. Cl. H01L 31/00; A45B 25/18

(52) U.S. Cl. 135/16; 136/252; 136/258

(57) ABSTRACT

A power generation umbrella includes solar energy components, including a solar energy absorption film, a solar energy accumulator, a transmission line, and an output interface, which are combined with an umbrella structure. The umbrella structure includes a canopy, a skeleton, a runner, and a central post. The solar energy absorption film is uniformly distributed over a top surface of the canopy. The solar energy accumulator and the output interface are arranged inside a hollow portion of the central post and are connected by the transmission line to the solar energy absorption film. The power generation umbrella features both shielding of sun light and rainwater, similar to a regular umbrella, and continuous supply of electrical power to serve a power source for an outdoor activity, so that there is no need for a user to carry a large capacity of power storage for the outdoor activity. The power generation umbrella makes the outdoor activity easy and convenient.

### BACKGROUND OF THE INVENTION

1. Field of the Invention

The present invention relates to a power generation umbrella, which comprises a power generation device that is composed of a solar energy absorption film, a solar energy accumulator, a transmission line, and an output interface elaborately arranged in an umbrella. The power generation umbrella provides the function of a regular umbrella or parasol and also functions to convert sun light into electrical power that is accumulated in the solar energy accumulator serving as back-up power for use by outdoor activity and leisure.

2. The Related Arts

A known umbrella or parasol only functions to shield users from sun light or rainwater. The function is thus very limited. With the gradually increased outdoor leisure and activity of modern people, taking a trip outdoor becomes very common. However, power supply in an outdoor environment is often difficult and bulky power storage or accumulator must be carried. This causes troubles and inconvenience to the outdoor activity.

### SUMMARY OF THE INVENTION

To overcome such a trouble and inconvenient condition, the present invention aims to provide a power generation umbrella.

In other words, the objective of the present invention is to combines solar energy components, including a solar energy absorption film, a solar energy accumulator, a transmission line, and an output interface, with an umbrella to feature the umbrella with both shielding of sun light and rainwater and continuous supply of electrical power, so as to resolve the trouble of lacking electrical power supply in an outdoor activity and make the outdoor activity and leisure easy and convenient.

To achieve the above objective, the present invention adopts the following solution.

The present invention provides a power generation umbrella, which comprises a solar energy absorption film, solar energy accumulator, transmission line, and an output interface, which are arranged in an umbrella structure.

The umbrella structure comprises a canopy, a skeleton, a runner, and a central post.

When the runner is forced upward along the central post, the skeleton is expanded to open the canopy. On the other hand, when the runner is moved downward along the central post, the skeleton is collapsed and the canopy is closed.

The solar energy absorption film is uniformly distributed over a top surface of the canopy.

The solar energy accumulator, the transmission line, and the output interface are arranged inside a hollow portion of the central post and are connected to the solar energy absorption film through the transmission line.

In a practical operation, the umbrella is positioned in a bright outdoor site, and the runner is operated to open the canopy, making the solar energy absorption film on the canopy facing sun light.

The solar energy absorption film then receives and absorbs the solar energy of the sun light and thermal energy and applies electrical power generated thereby through the transmission line to the solar energy accumulator to be stored therein as back-up power for subsequent use.

The output interface selectively comprises various types of power sockets or receptacles to allow for plugging by a user who needs the supply of electrical power to enjoy outdoor activities and leisure.

### BRIEF DESCRIPTION OF THE DRAWINGS

The present invention will be apparent to those skilled in the art by reading the following description of preferred embodiments thereof, with reference to the attached drawings, wherein:

FIG. 1 is a schematic view showing a central post and a skeleton a power generation umbrella constructed in accordance with the present invention; and

FIG. 2 is a schematic view showing the central post a canopy of the power generation umbrella constructed in accordance with the present invention.

### DETAILED DESCRIPTION OF THE PREFERRED EMBODIMENTS

A description of a power generation umbrella constructed in accordance with the present invention will be now described in details with reference to the attached drawings.

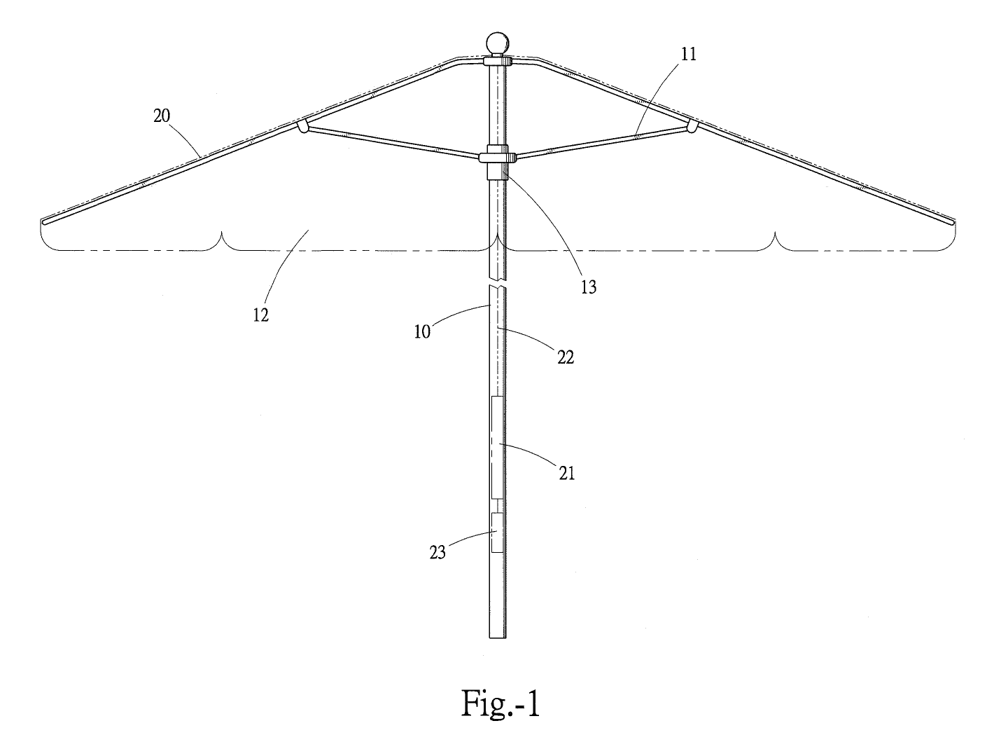

FIG. 1 provides a schematic view illustrating the structure of a central post 10 and a skeleton 11 of the power generation umbrella of the present invention.

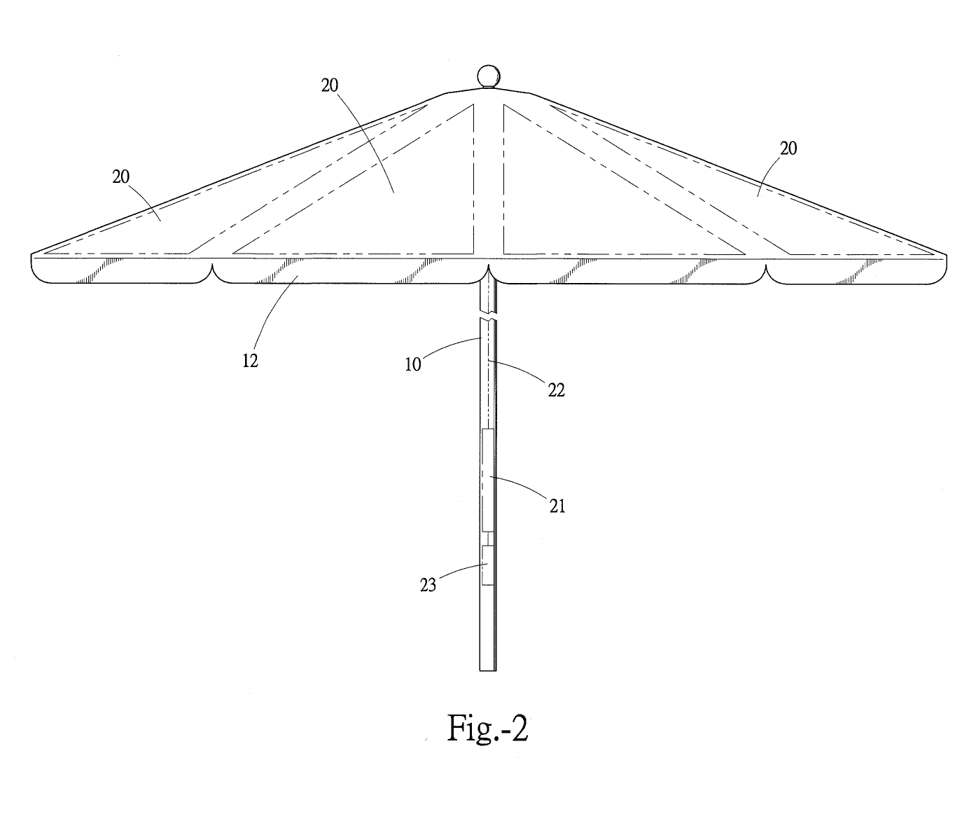

FIG. 2 provides a schematic view illustrating the structure of the central post 10 and a canopy or an umbrella panel 12 of the power generation umbrella of the present invention.

As shown in FIG. 1, the power generation umbrella of the present invention generally comprises a solar energy absorption film 20, a solar energy accumulator 21, a transmission line 22, and an output interface 23, which are together arranged in an umbrella structure to form the power generation umbrella of the present invention.

As shown in FIG. 1, the umbrella structure to which the present invention is applicable comprises the canopy 12, the skeleton 11, a runner 13, and the central post 10, which are properly assembled together in any known manner.

Further as shown in FIG. 1, when the runner 13 is forced upward along the central post 10, the runner 13 expand the skeleton 11 to open the canopy 12. On the other hand, when the runner 13 is moved downward along the central post 10, the runner 13 collapse the skeleton 11 to close the canopy 12.

As shown in FIG. 2, the solar energy absorption film 20 is uniformly spread over and attached to a top surface of the canopy 12.

As shown in FIGS. 1 and 2, the solar energy accumulator 21, the transmission line 22, and the output interface 23 are set inside a hollow tubular portion of the central post 10 and are connected through the transmission line 22 to the solar energy absorption film 20 that is arranged atop the canopy 12.

The solar energy absorption film 20 comprises a flexible thin article having excellent machinability. Examples include crystalline silicon, such as polysilicon thin film or amorphous silicon thin film. The solar energy absorption film 20 provides the function of conversion of solar energy into electrical power.

In a practical operation, the power generation umbrella of the present invention is positioned in a bright outdoor location. The runner 13 is operated to open the canopy 12, making the solar energy absorption film 20 that is arranged on the canopy 12 facing the sun light.

The solar energy absorption film 20 then receives and absorbs the solar energy carried by the sun light and applies electrical power generated thereby through the transmission line 22 to the solar energy accumulator 21 to be stored therein as back-up power for subsequent use.

The output interface 23 selectively comprises various types of power sockets or receptacles to allow for plugging by a user who needs the supply of electrical power to enjoy outdoor activities and leisure.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A power generation umbrella, comprising:
an umbrella structure comprising a canopy, a skeleton, a runner, and a central post;
a solar energy absorption film, which is uniformly distributed over a top surface of the canopy, adapted to receive light and convert the light into electrical power;
a solar energy accumulator, which is arranged inside a hollow portion of the central post of the umbrella structure;
a transmission line, which is arranged inside the central post to connect between the solar energy absorption film and the solar energy accumulator to supply the electrical power from the solar energy absorption film to the solar energy accumulator to be stored therein; and
an output interface, which is mounted to the central post and adapted to supply the electrical power stored in the solar energy accumulator to a user.

2. The power generation umbrella as claimed in claim 1, wherein the solar energy absorption film comprises a polysilicon thin film.

3. The power generation umbrella as claimed in claim 1, wherein the solar energy absorption film comprises an amorphous silicon thin film.

4. The power generation umbrella as claimed in claim 1, wherein the output interface comprises a power socket.

5. The power generation umbrella as claimed in claim 1, wherein the output interface comprises a receptacle.
